(19) United States
(12) Patent Application Publication
(10) Pub. No.: US 2018/0035062 A1
(43) Pub. Date: Feb. 1, 2018

(54) IMAGE CAPTURING APPARATUS HAVING COMPARATOR CIRCUIT TO COMPARE CURRENT WITH REFERENCE CURRENT

(71) Applicant: CANON KABUSHIKI KAISHA, Tokyo (JP)

(72) Inventors: Kentaro Tsukida, Yokohama-shi (JP); Masanobu Ohmura, Yokohama-shi (JP)

(21) Appl. No.: 15/656,919

(22) Filed: Jul. 21, 2017

(30) Foreign Application Priority Data
Jul. 29, 2016 (JP) 2016-150329

(51) Int. Cl. H04N 5/355; H04N 5/378; H01L 27/146

(52) U.S. Cl. CPC H04N 5/355; H01L 27/14614; H01L 27/14636; H01L 27/14641; H04N 5/378

(57) ABSTRACT

A plurality of pixels includes a photoelectric conversion unit and the first transistor. A signal line is connected to the plurality of pixels. A second transistor includes a source or a drain electrically connected to the first transistor and includes a gate supplied with a signal corresponding to a reference signal of which a potential changes at a predetermined gradient with time. A first current source is configured to supply a current to the first and second transistors. A control unit is configured to control a voltage between a gate and a source of a third transistor to be a voltage corresponding to a voltage between the gate and the source of the second transistor. A comparator circuit is configured to compare a first current flowing through the third transistor with a reference current.

### BACKGROUND OF THE INVENTION

### Field of the Invention

One disclosed aspect of the embodiments relates to an image capturing apparatus.

### Description of the Related Art

Japanese Patent Application Laid-Open No. 2005-311487 (hereinbelow, referred to as the patent literature 1) describes an image capturing apparatus including a pixel array in which a plurality of pixels is arranged. The plurality of pixels forms a plurality of pixel columns each including at least two pixels. In the image capturing apparatus described in the patent literature 1, each pixel column is provided with one differential transistor. Each amplification transistor of the plurality of pixels included in one pixel column forms a differential pair with a corresponding differential transistor.

A source of the differential transistor and a source of the amplification transistor are connected to a constant current source via signal lines. To a gate of the amplification transistor, a signal based on a charge generated in a photoelectric conversion unit is input. A gate of the differential transistor is supplied with a lamp signal. A drain of the differential transistor is connected to a load transistor. The differential pair forms a comparator circuit with the above-described circuit configuration. A potential of the drain of the differential transistor is changed according to a relationship between a potential of the gate of the amplification transistor and a potential of the gate of the differential transistor.

### SUMMARY OF THE INVENTION

An exemplary embodiment according to an aspect of the present disclosure is an image capturing apparatus including a plurality of pixels having a photoelectric conversion unit and a first transistor, a signal line, a second transistor, a first current source, a control unit, and a comparator circuit. The pixel includes the photoelectric conversion unit and the first transistor having a gate to which a signal based on a charge generated in the photoelectric conversion unit is input. The signal line is connected to the plurality of pixels. The second transistor includes a source electrically connected to the first transistor via the signal line and includes a gate supplied with a signal corresponding to a reference signal of which a potential changes at a predetermined gradient with time. The first current source is configured to supply a source current to the first transistor and the second transistor. The control unit is configured to control a voltage between a gate and a source of a third transistor to be a voltage corresponding to a voltage between the gate and the source of the second transistor. The comparator circuit is configured to compare a first current flowing through the third transistor with a reference current.

Further features of the disclosure will become apparent from the following description of exemplary embodiments with reference to the attached drawings.

### BRIEF DESCRIPTION OF THE DRAWINGS

FIG. 1 is a block diagram illustrating an image capturing apparatus.

FIG. 2 is an equivalent circuit diagram illustrating a pixel circuit and a comparator circuit.

FIG. 3 is a schematic diagram of a timing chart.

FIG. 4 is an equivalent circuit diagram illustrating a pixel circuit and a comparator circuit.

FIG. 5 is a schematic diagram of a timing chart.

FIG. 6 is an equivalent circuit diagram illustrating a pixel circuit and a comparator circuit.

FIG. 7 is an equivalent circuit diagram illustrating a pixel circuit and a comparator circuit for describing the comparative example.

FIG. 8 is a block diagram illustrating an exemplary embodiment of a photoelectric conversion system.

FIGS. 9A and 9B are block diagrams illustrating exemplary embodiments of a mobile body.

### DESCRIPTION OF THE EMBODIMENTS

According to the patent literature 1, the drain of the differential transistor is connected to a power supply line via the load transistor. In order to stably operate the load transistor, it is necessary to generate a potential difference between the drain and the source by setting a potential of the drain of the load transistor lower with respect to that of the source of the load transistor. In other words, it is necessary to set the potential of the drain of the differential transistor lower compared to a power source potential.

As the potential of the drain of the differential transistor is lowered, a potential of the source of the differential transistor is lowered. Thus, a potential of the source of the amplification transistor is also lowered. As a result, there is a possibility of limiting a range in which a potential of the gate as an input node of the amplification transistor can be obtained. Thus, there is a possibility of narrowing a dynamic range of the input node of the amplification transistor.

Some exemplary embodiments according to the present disclosure can expand a dynamic range of an input node of an amplification transistor.

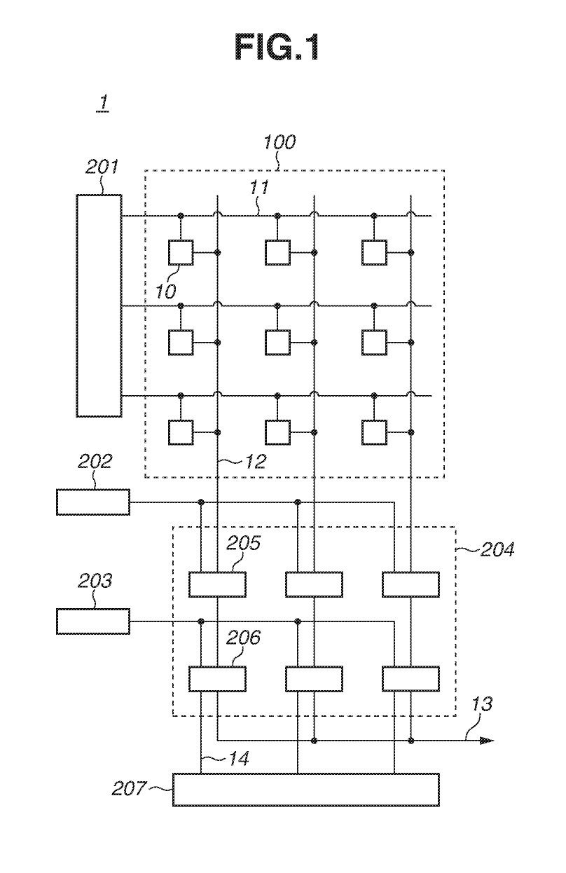

FIG. 1 is a block diagram schematically illustrating an entire configuration of an image capturing apparatus 1 according to a first exemplary embodiment. Parts with the same reference numerals in each drawing indicates the same elements, the same regions, the same driving pulses, or the same potentials.

A plurality of pixels 10 constitutes a pixel array 100. The pixel array 100 includes a plurality of pixel rows and a plurality of pixel columns. According to the present exemplary embodiment, a row direction expresses an arranging direction of pixels in the pixel row, and a column direction expresses an arranging direction of pixels in the pixel column.

A vertical scanning circuit 201 supplies driving pulses pRES, pTX, and pSEL for controlling a transistor of each pixel 10. These driving pulses are common to each pixel row. In other words, the transistors of the plurality of pixels included in one pixel row are connected to a common control line. On the other hand, the plurality of pixels included in one pixel column is connected to a common signal line. A signal line 12 connects each pixel 10 and a column circuit 204.

In FIG. 1, three column circuits 204 are illustrated. One column circuit 204 is arranged corresponding to one pixel column. The column circuit 204 includes a comparator circuit 205 and a latch circuit 206. Further, a reference signal output circuit unit 202 and a counter circuit 203 are commonly arranged with respect to a plurality of the column circuits 204.

The comparator circuit 205 is connected to the reference signal output circuit unit 202. The reference signal output circuit unit 202 supplies a reference signal to the comparator circuit 205. A potential of the reference signal is changed with time at a predetermined gradient. The reference signal is, for example, a lamp signal. In addition, as described above, the comparator circuit 205 is connected to the pixel 10 via the signal line 12. The comparator circuit 205 compares a signal of the pixel 10 with the reference signal by the above-described configuration.

The comparator circuit 205 outputs a control signal based on the comparison result. In each column circuit 204, the control signal output from the comparator circuit 205 is input to the latch circuit 206. Further, a count value from the counter circuit 203 is input to the latch circuit 206 in each column circuit 204.

The counter circuit 203 changes a count value to output as time passes. The counter circuit 203 starts to change the count value in synchronization with a start of a potential change in the reference signal output from the reference signal output circuit unit 202.

The latch circuit 206 holds the count value input from the counter circuit 203 when receiving the control signal output from the comparator circuit 205. The count value held in the latch circuit 206 in this time is a digital signal obtained by performing analog to digital conversion (hereinbelow, referred to as the AD conversion) on a signal of the pixel 10. Subsequently, the latch circuit 206 outputs the held digital signal to a signal line 13 in response to a driving pulse from a horizontal scanning circuit 207.

The horizontal scanning circuit 207 is connected to the latch circuit 206 arranged with respect to each pixel column via a signal line 14. The horizontal scanning circuit 207 sequentially outputs the relevant digital signal from the image capturing apparatus 1 via the signal line 13.

According to the exemplary embodiment illustrated in FIG. 1, the counter circuit 203 is commonly arranged to the column circuits 204. As a variation, a plurality of the column circuits 204 may each include the counter circuit 203. In this case, the counter circuit 203 of each pixel column receives the control signal based on the comparison result from the corresponding comparator circuit 205. Then, the counter circuit 203 stops counting at a timing when receiving the control signal. The count value when counting is stopped is a digital signal as a result of the AD conversion performed on the signal of the pixel 10.

The configuration in which the reference signal output circuit unit 202, the counter circuit 203, and the horizontal scanning circuit 207 are included in the image capturing apparatus 1 is described, however, these units may be included in an apparatus other than the image capturing apparatus 1.

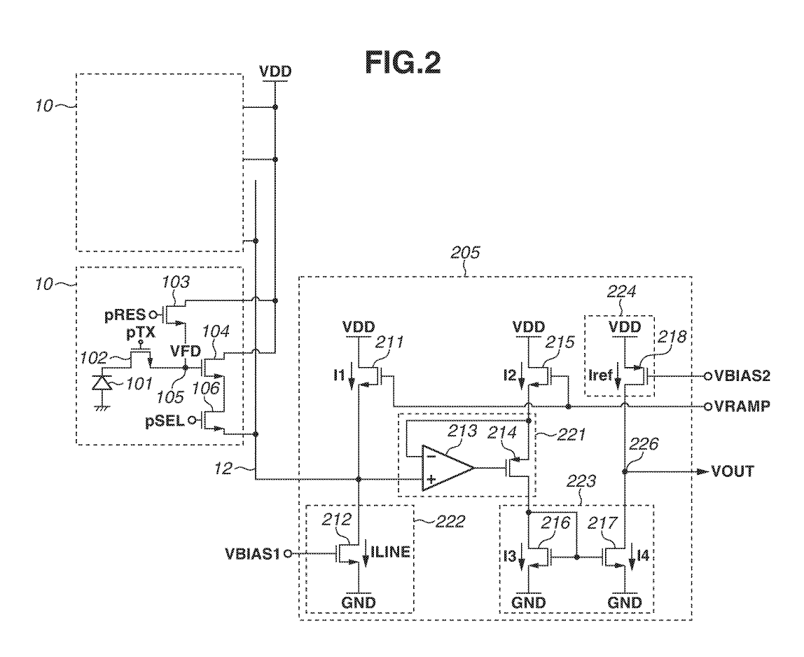

FIG. 2 is an equivalent circuit diagram illustrating the pixel 10 and the comparator circuit 205 in the image capturing apparatus 1. One comparator circuit 205 is arranged to the plurality of the pixel 10 included in one pixel column. In FIG. 2, only two pixels 10 are illustrated to simplify the description. Further according to the present exemplary embodiment, an electron in a charge pair generated in a photoelectric conversion unit is used as a signal charge.

In the present specification, a signal charge may be simply referred to as a charge below. Further, unless otherwise noted, each transistor is a negative channel metal oxide semiconductor (NMOS) transistor, and when a positive channel metal oxide semiconductor (PMOS) transistor which is a conductivity type reverse to the NMOS transistor is used, it is described accordingly. In equivalent circuit diagrams in FIGS. 2, 4, 6, and 7, sources of transistors are illustrated as arrows. The NMOS transistor is illustrated with an arrow directed from a gate to a source. Similarly, the PMOS transistor is illustrated with an arrow directed from a source to a gate. When a hole is used as a signal charge, a conductivity type of each transistor is reversed.

The pixel 10 includes a photoelectric conversion unit 101, a reset transistor 103, a transfer transistor 102, a transistor 104 (a first transistor), and a selection transistor 106. The photoelectric conversion unit 101 generates a charge pair in response to incident light and accumulates a charge as a signal charge. For example, a photodiode is used as the photoelectric conversion unit 101.

To a floating diffusion unit 105 (hereinbelow, referred to as the FD 105), the signal charge is transferred from the photoelectric conversion unit 101 via the transfer transistor 102. The FD 105 holds the transferred charge. The transfer transistor 102 transfers a charge generated in the photoelectric conversion unit 101 to the FD 105. The transfer transistor 102 is supplied with the driving pulse pTX and switched ON and OFF. When the transfer transistor 102 is turned ON, a charge is transferred.

An input node of the transistor 104 is constituted of the FD 105, a wiring connected to a gate of the transistor 104, and a source of the reset transistor 103. A source of the transistor 104 is connected to a first current source 222 via the selection transistor 106 and the signal line 12.

The transistor 104 constitutes a source follower circuit together with the first current source 222 by the above-described configuration. The transistor 104 amplifies a signal based on the charge transferred to the FD 105 and outputs the signal to the signal line 12. More specifically, the charge transferred to the FD 105 is converted to a potential corresponding to an amount thereof by the FD 105. The transistor 104 outputs a potential corresponding to the potential of the FD 105 to the signal line 12.

The reset transistor 103 resets the potential of the input node of the transistor 104 to a potential near a power source potential VDD. A gate of the reset transistor 103 is supplied with the driving pulse pRES and switched ON and OFF.

The selection transistor 106 causes the plurality of the pixels 10 provided to one signal line 12 to output the signal per pixel or plurality of pixels. A drain of the selection transistor 106 is connected to the source of the transistor 104, and a source of the selection transistor 106 is connected to the signal line 12. A gate of the selection transistor 106 is supplied with the driving pulse pSEL, and the selection transistor 106 functions as a switch for switching electrical connection and disconnection between the signal line 12 and the transistor 104 and thus selects a row.

In place of the configuration according to the present exemplary embodiment, the selection transistor 106 may be disposed between a drain of the transistor 104 and a power source wiring supplied with a power source voltage VDD. Alternatively, the source of the transistor 104 may be connected to the signal line 12 without disposing the selection transistor 106.

The image capturing apparatus 1 includes the comparator circuits 205 for each of the plurality of the pixel columns. The comparator circuit 205 includes a transistor 211, a transistor 215, the first current source 222, a control unit 221, a second current source 224, and a current mirror circuit 223.

A transistor 212 constitutes the first current source 222. The transistor 212 includes a gate supplied with a bias voltage VBIAS1, a source supplied with a ground potential GND, and a drain connected to a source of the transistor 211 and the signal line 12. The bias voltage VBIAS1 controls magnitude of a current ILINE output from the first current source 222.

A gate of the transistor 211 is supplied with a reference signal VRAMP output from the reference signal output circuit unit 202. The transistor 211 includes a drain supplied with the power source voltage VDD without a transistor and a source connected to the signal line 12. A current I1 flows through the transistor 211.

The signal line 12 is connected to a drain of the transistor 212 which constitute the first current source 222 and the source of the transistor 211. The transistor 104 and the transistor 211 form a differential pair sharing the first current source 222. A potential of the signal line 12 is expressed as a potential VLINE.

A drain of the transistor 215 is supplied with the power source voltage VDD without a transistor. A source of the transistor 215 is connected to an inversion input terminal of a differential amplifier circuit 213 and a source of a PMOS transistor 214. A reference signal same as the reference signal VRAMP supplied to the gate of the transistor 211 is supplied to a gate of the transistor 215. A current I2 (a first current) flows through the transistor 215.

The control unit 221 includes the differential amplifier circuit 213 and the PMOS transistor 214. A non-inversion input terminal of the differential amplifier circuit 213 is connected to the signal line 12.

An output terminal of the differential amplifier circuit 213 is connected to a gate of the PMOS transistor 214. An inversion input terminal of the differential amplifier circuit 213 is connected to the source of the transistor 215 and a source of the PMOS transistor 214. Accordingly, the inversion input terminal and the non-inversion input terminal of the differential amplifier circuit 213 are in a virtually short-circuited state (virtual short). In other words, the differential amplifier circuit 213 controls a potential of the source of the PMOS transistor 214 to be the same as the potential VLINE of the source of the transistor 211.

A drain of the PMOS transistor 214 is connected to a drain of a transistor 216. The PMOS transistor 214 controls electrical connection between the transistor 215 and the transistor 216 included in the current mirror circuit 223.

According to the present exemplary embodiment, the same reference signal VRAMP is supplied to the gate of the transistor 211 and the gate of the transistor 215. Further, the source of the transistor 215 is supplied with a potential approximately the same as the potential of the source of the transistor 211 by the virtual short constituted of the differential amplifier circuit 213. Thus, a voltage between the gate and the source of the transistor 215 corresponds to a voltage between the gate and the source of the transistor 211. Further, the current flowing through the transistor 215 corresponds to the current I1 flowing through the transistor 211.

Here, “correspond” means that when the current I1 of the transistor 211 changes, the current I2 of the transistor 215 changes in the same direction. For example, when parameters such as a channel width, a channel length, and a threshold voltage are the same between the transistor 211 and the transistor 215, the currents flowing through the both transistors have approximately the same magnitude.

The transistor 216 and a transistor 217 constitute the current mirror circuit 223. A source of the transistor 216 is supplied with the ground potential GND. The drain and a gate of the transistor 216 are short-circuited with each other. Further, the drain and the gate of the transistor 216 are connected to the drain of the PMOS transistor 214 and a gate of the transistor 217.

A source of the transistor 217 is supplied with the ground potential GND. A drain of the transistor 217 is connected to the second current source 224. The drain of the transistor 216 constitutes an input node of the current mirror circuit 223, and the drain of the transistor 217 constitutes an output node of the current mirror circuit 223.

A current I3flows through the transistor 216. A current I4 flows through the transistor 217. The transistor 215 and the transistor 216 are connected in series in one electrical path, so that magnitude of the current I1 of the transistor 215 is approximately the same as magnitude of the current I3of the transistor 216.

A ratio of the current I4 to the current I3 is determined according to a ratio of parameters of the transistor 216 and the transistor 217. In other words, in the current mirror circuit 223, the current I2 flowing through the transistor 215 can be copied to the current I4 flowing through the transistor 217 according to parameters of each transistor. According to the present exemplary embodiment, a current mirror circuit ratio of the transistor 216 and the transistor 217 is described as 1:2.

A PMOS transistor 218 constitutes the second current source 224. The PMOS transistor 218 includes a gate supplied with a bias voltage VBIAS2, a source supplied with the power source voltage VDD, and a drain connected to the drain of the transistor 217. A reference current Iref flows through the PMOS transistor 218. The bias voltage VBIAS2 controls magnitude of the reference current Iref. According to the present exemplary embodiment, the magnitude of the reference current Iref is approximately the same as magnitude of the current ILINE generated in the transistor 212.

A node to which the drain of the transistor 217 and a drain of the PMOS transistor 218 are connected constitutes an output node 226 of the comparator circuit 205. An output signal VOUT output from the output node 226 is input to the latch circuit 206.

In the description of each transistor, the example is described in which the drain or the source is directly connected to the wiring supplying the power source voltage VDD. However, an element such as a switch and a capacitor may be arranged between the wiring supplying the power source voltage VDD and the transistor. This configuration can be similarly applied to other exemplary embodiments.

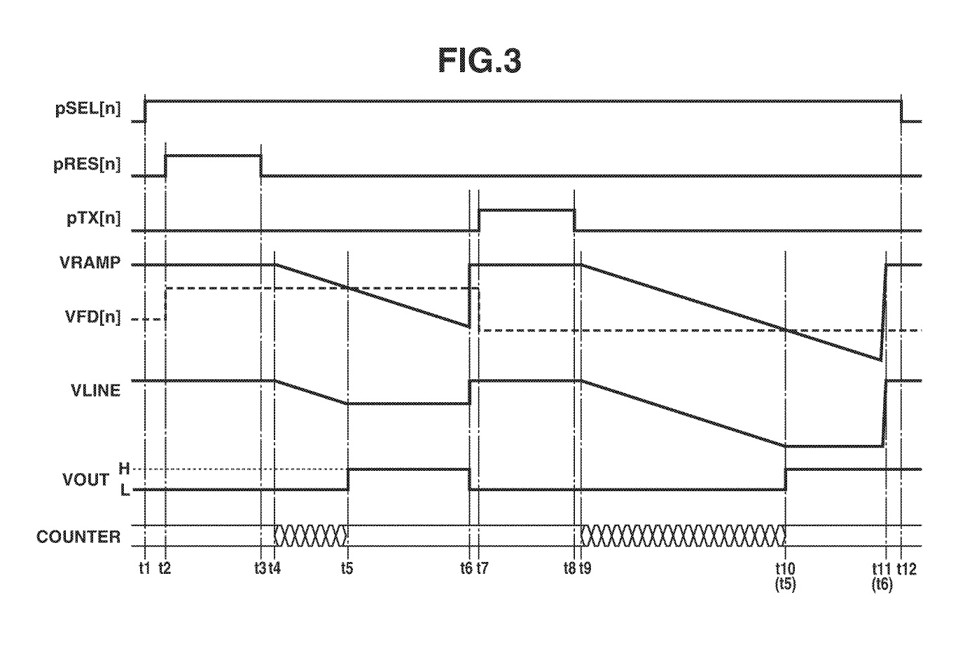

Next, a comparison operation of the signal based on the charge generated in the photoelectric conversion unit 101 and the reference signal VRAMP according to the present exemplary embodiment is described. FIG. 3 is a schematic diagram of a timing chart illustrating an example of driving pulses input to pixels in one pixel row for performing the comparison operation. In FIG. 3, rectangular waves are used to simplifying the description, however, the driving pulses need not necessarily be complete rectangular shapes.

The driving pulses supplied to the pixels 10 in an N-th row of the pixel rows arranged in the pixel array 100 are described as an example of the driving pulses supplied to the plurality of the pixels 10.

Specifically, the driving pulses pSEL[n], pRES[n], and pTX[n] represent driving pulses input to each transistor in an arbitrary n-th row among driving pulses output from the vertical scanning circuit 201. A potential VFD[n] is a potential of the input node of the transistor 104 of an arbitrary pixel 10 in the n-th row, namely the FD 105. FIG. 3 illustrates a potential VLINE of the signal line 12, an output signal VOUT of the comparator circuit 205, and the reference signal VRAMP input to the gate of the transistor 215 and the gate of the transistor 211.

In the circuit configuration in FIG. 2, a threshold voltage of the transistor 104 is a threshold voltage VTH1, and a threshold voltage of the transistor 215 is a threshold voltage VTH2. An inequality 1 is a condition that the transistor 104 is turned ON.

VFD[n]−VLINE>VTH1 (1)

First, a state in which the transistor 104 is turned OFF is described. In this state, the transistor 211 and the first current source 222 constitute a source follower circuit. Thus, the potential VLINE of the signal line 12 is expressed as VLINE=VRAMP−VTH2. Therefore, the condition that the transistor 104 is turned ON is expressed by an inequality 2 and an inequality 3 as a modification of the inequality 2.

VFD[n]−(VRAMP−VTH2)>VTH1 (2)

VFD[n]>VRAMP +VTH1−VTH2 (3)

According to the present exemplary embodiment, the parameters such as the channel width, the channel length, and the threshold voltage of the transistor 211 and the transistor 215 are the same as parameters such as a channel width, a channel length, and the threshold voltage of the transistor 104. In other words, the threshold voltage VTH1 is equal to the threshold voltage VTH2. In that case, an inequality 4 can be obtained from the inequality 3 as the condition that the transistor 104 is turned ON.

VFD[n]>VRAMP (4)

When the inequality 4 is satisfied, and the transistor 104 is turned ON, the transistor 104 operates as the source follower circuit. Thus, the potential VLINE of the signal line 12 is VLINE=VFD[n]−VTH1. Here, a condition that the transistor 211 is turned ON is VRAMP −VLINE >VTH2.

When the threshold voltage VTH1 of the transistor 104 is equal to the threshold voltage of the transistor 211, the condition that the transistor 211 is turned ON is rewritten to VRAMP>VFD[n]. In other words, when the inequality 4 is satisfied, the transistor 211 is turned OFF. When the transistor 211 is turned OFF, almost no current flows through the transistor 211. Alternatively, the current I1 of the transistor 211 is almost zero.

As described above, when the potential VRAMP of the reference signal is high, the transistor 104 is turned OFF, and the transistor 211 is turned ON. When the potential VFD of the FD 105 is high, the transistor 104 is turned ON, and the transistor 211 is turned OFF. According to the present exemplary embodiment, whether the transistor 104 is turned ON or not by comparing the potentials VFD[n] and VRAMP is described below for simplifying the description. However, when the parameters are not the same in the transistor 104 and the transistor 211, a difference between the threshold voltage VTH1 of the transistor 104 and the threshold voltage of the transistor 211 VTH2 can be considered as expressed by the inequality 3.

At a time t1 in FIG. 3, a driving pulse pSEL[n] signal becomes a high level (an H level), and the selection transistor 106 enters an ON state. The pixel 10 in the n-th row is electrically connected to the signal line 12. A start voltage of the reference signal VRAMP is set to a higher potential than a reset potential of the potential VFD of the FD 105.

In a period t2-t6, the AD conversion is performed on the reset potential which is the potential of the FD 105 when the pixel 10 is reset.

At a time t2, the driving pulse pRES[n] becomes the H level, and the reset transistor 103 enters the ON state. Accordingly, the potential VFD[n] of the FD 105 of the pixel 10 in the n-th row becomes the reset potential. The start voltage of the reference signal VRAMP is in the higher potential than the reset potential.

At that time, the potential VFD and the reference signal VRAMP do not satisfy a relationship of the inequality 4, and the transistor 104 enters an OFF state. On the other hand, the transistor 211 and the transistor 215 enter the ON state. When the transistor 211 is in the ON state, the current I1 flows through the transistor 211. At that time, the current I2 corresponding to the current I1 flows through the transistor 215. The current does not flow through the transistor 104 in the OFF state, so that magnitude of the current I2 in the transistor 211 is approximately equal to the current ILINE.

At a time t3, the driving pulse pRES[n] becomes a low level (an L level), and the reset transistor 103 enters the OFF state.

At a time t4, the potential of the reference signal VRAMP starts to change. In addition, the counter circuit 203 starts counting at the same time with the start of the change in the reference signal VRAMP. In other words, the count value output from the counter circuit 203 and input to the latch circuit 206 starts to change.

In a period t2-t4, the reference signal VRAMP is in the higher potential than the potential VFD[n] of the FD 105 and constant. Thus, the inequality 4 is not satisfied, and the transistor 104 is turned OFF. In other words, a voltage Vgs between the gate and the source of the transistor 104 —a threshold value VTH1<0 is satisfied.

Further, as described above, the same reference signal VRAMP is supplied to the gate of the transistor 211 and the gate of the transistor 215. Furthermore, the source of the transistor 215 is supplied with a potential equivalent to that of the source of the transistor 211 by the virtual short. Thus, the voltage between the gate and the source of the transistor 215 is approximately the same as the voltage between the gate and the source of the transistor 211. Accordingly, the current I2 which is almost the same magnitude of the current I1 flowing through the transistor 211 flows through the transistor 215.

The magnitude of the current I1 flowing through the transistor 211 is approximately equal to the magnitude of the current ILINE. Thus, the magnitude of the current flowing through the transistor 215 is approximately equal to the magnitude of the current VLINE. However, when the parameters of the transistor 211 are different from the parameters of the transistor 215, current values are different according to a difference therebetween.

The current mirror circuit 223 constituted of the transistor 216 and the transistor 217 has the mirror ratio of 1:2. Thus, magnitude of the current I4 flowing through the transistor 217 is about twice as large as magnitude of the current I3 flowing through the transistor 216. In other words, the magnitude of the current I4 is about twice as large as the magnitude of the current ILINE.

On the other hand, magnitude of the reference current Iref of the PMOS transistor 218 is approximately equal to the magnitude of the current ILINE. Thus, a potential of the output node 226 is lowered. Further, the potential of the output node 226 becomes stable at a low potential (a potential at the L level) at which the current flowing through the transistor 217 converges on the reference current Iref. Thus, the output signal VOUT of the comparator circuit 205 input to the latch circuit 206 in the latter stage becomes the L level.

In a period t4-t5, the potential of the reference signal VRAMP input to the potential of the gate of the transistor 211 is gradually lowered, and accordingly, the potential VLINE of the signal line 12 is lowered. In the case in FIG. 3, the transistor 211 is in the ON state until the reference signal VRAMP is lowered to the potential VFD. Thus, during this period, the current mirror circuit 223 outputs the current I4 which is approximately twice as large as the current ILINE.

In the period t4-t5, the magnitude of the reference current Iref flowing through the PMOS transistor 218 is also approximately the same as the magnitude of the current ILINE. Thus, the output signal VOUT remains in the low potential (the potential at the L level).

At a time t5, a magnitude relationship between the reference signal VRAMP and the potential VFD[n] of the FD 105 is inverted. The potential VFD and the reference signal VRAMP satisfy the relationship in the inequality 4, and the transistor 104 is turned ON. Further, the reference signal VRAMP becomes smaller than the potential VFD[n], and the transistor 211 is turned OFF. In other words, the voltage between the gate and the source of the transistor 211 becomes a value for turning the transistor 211 OFF.

At that time, the control unit 221 controls the voltage between the gate and the source of the transistor 215 so as to correspond to the voltage between the gate and the source of the transistor 211. Specifically, according to the present exemplary embodiment, the voltage between the gate and the source of the transistor 211 becomes approximately equal to the voltage between the gate and the source of the transistor 215. Accordingly, the transistor 215 is turned OFF as with the transistor 211. The current I2 of the transistor 215 ceases to flow, and accordingly, the current I4 also ceases to flow.

On the other hand, the PMOS transistor 218 outputs the current Iref. Thus, the potential of the output node 226 is raised, and the output signal VOUT of the comparator circuit 205 becomes a high potential (a potential at the H level). As described above, when the magnitude relationship between the reference signal VRAMP and the potential VFD[n] is inverted, the potential of the output node 226 is raised, and the output signal VOUT is inverted. Further, the latch circuit 206 holds the count value output from the counter circuit 203 in response to a change in the output signal VOUT.

At a time t6, the reference signal VRAMP is reset to a start potential. The transistor 211 and the transistor 215 are turned ON, and the transistor 104 is turned OFF. Further, the potential of the output node 226 is raised, and the output signal VOUT becomes the low potential (the potential at the L level). By the operations so far, the AD conversion of the reset signal of the pixel 10 is completed.

In a period t5-t6, the reference signal VRAMP becomes lower than that at the time t5, however, the potential VLINE is not lowered from the value at the time t5. This is because that the potential VLINE of the signal line 12 is determined by the output of the transistor 104 in the pixel 10 in the period t5-t6. Specifically, the potential VLINE of the signal line 12 is maintained at a potential lowered by the threshold voltage VTH1 of the transistor 104 from the potential of the FD 105. Therefore, the output signal VOUT maintains the potential at the H level.

In a period t7-t11, the AD conversion is performed on the signal based on the charge generated in the photoelectric conversion unit 101 of the pixel 10.

At a time t7, the driving pulse pTX[n] becomes the H level, and the transfer transistor 102 enters the ON state. At a time t8, the driving pulse pTX[n] becomes the L level, and the transfer transistor 102 enters the OFF state. Accordingly, the charge generated in the photoelectric conversion unit 101 is transferred to the FD 105, and the potential of the gate of the transistor 104 is changed. Driving in a period t9-t11 is similar to the driving in the period t4-t6, and thus the description thereof is omitted.

At a time t12, the driving pulse pSEL becomes the L level, the selection transistor 106 enters the OFF state, and the row selection is completed.

According to the configuration of the present exemplary embodiment, a transistor to be a load is not arranged between a drain of the transistor 211 constituting a differential pair with the transistor 104 of the pixel 10 in each pixel column and the node supplying the power source voltage VDD.

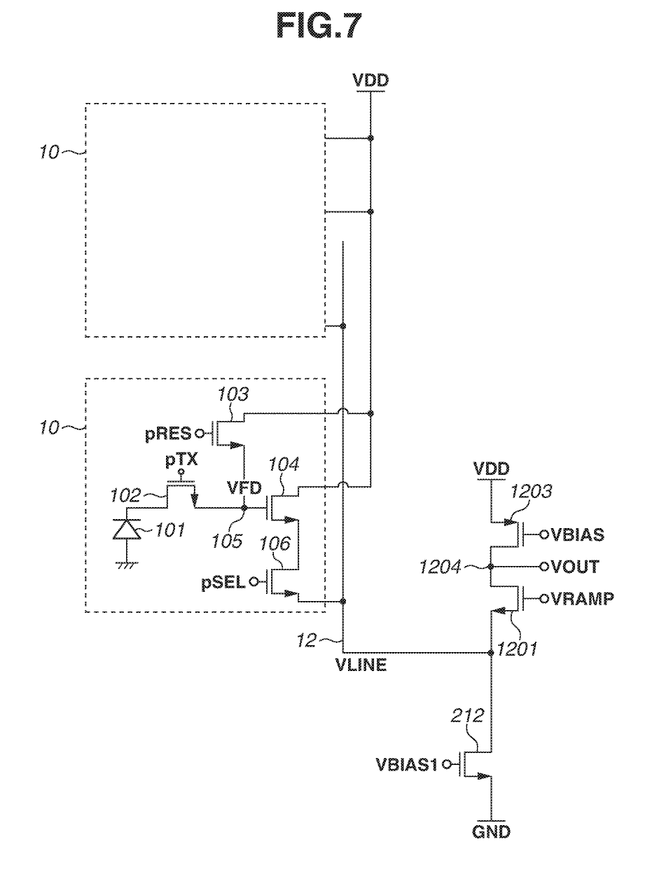

An effect of the configuration is described with reference to a comparative example. FIG. 7 is an equivalent circuit diagram of the comparative example. A transistor 1201 in FIG. 7 corresponds to the transistor 211 in FIG. 2. A source of the transistor 1201 is connected to the first current source 222. A drain of the transistor 1201 is connected to a node 1204 and a drain of a PMOS transistor 1203. A gate of the transistor 1201 is supplied with the reference signal VRAMP. A source of the PMOS transistor 1203 is connected to the power source voltage VDD. A gate of the PMOS transistor 1203 is supplied with a bias voltage VBIAS.

As described above, in the configuration in FIG. 7, a potential of the drain of the transistor 1201 is used as the output signal VOUT, and thus the PMOS transistor 1203 is arranged as a load between the drain of the transistor 1201 and a node supplying the power source voltage VDD. This is because that if the power source voltage VDD is directly supplied to the drain of the transistor 1201, a potential of the node 1204 constantly becomes the power source voltage VDD.

According to the comparative example in which the PMOS transistor 1203 is connected to the drain of the transistor 1201, a voltage between the drain and the source of the PMOS transistor 1203 is secured to operate the PMOS transistor 1203. In other words, a potential of the drain of the PMOS transistor 1203 is set lower than the power source voltage VDD. Thus, a potential of the drain of the transistor 1201 is lower than the power source voltage VDD. In addition, a potential of the source of the transistor 1201 is further lower than the potential of the drain of the transistor 1201 so as to secure a voltage between the drain and the source for operating the transistor 1201.

For example, in the circuit in FIG. 7, a case when the potential of the reference signal VRAMP is higher than the potential VFD of the FD 105 is assumed. The gate of the PMOS transistor 1203 is supplied with the bias voltage VBIAS which is sufficiently lower than the power source voltage VDD, so that the PMOS transistor 1203 is in the ON state.

When a potential difference between the gate and the source of the transistor 1201 is greater than the threshold voltage, the transistor 1201 is turned ON. Since the voltage of the reference signal VRAMP is high, a voltage of a gate of a transistor 1201 is relatively high at that time. On the other hand, a voltage of a source of the transistor 1201 is changed to a low potential by the transistor 212 as a current source. Therefore, the voltage between the gate and the source of the transistor 1201 is greater than the threshold voltage. In other words, the transistor 1201 is turned ON.

Thus, an ON-resistance R1 of the PMOS transistor 1203, an ON-resistance R2 of the transistor 1201, and an ON-resistance R3 of the transistor 212 as the current source are in a state being connected in series between the node of the power source voltage VDD and a ground node.

Thus, a voltage VOUT of an output node is expressed as the power source voltage VDD * (R2+R3)/(R1+R2+R3). Further, a voltage VLINE of the signal line 12 is expressed as the power source voltage VDD * (R3)/(R1+R2+R3). However, it is assumed that the transistor 104 is turned OFF. In other words, the potential VFD of the FD 105 is lower than a value obtained by adding the threshold voltage of the transistor 104 to the potential VLINE (the potential of the source of the transistor 104).

Next, a care when the voltage of the reference signal VRAMP becomes lower than the potential VFD of the FD 105 is assumed. Since the potential of the reference signal VRAMP is lowered, the potential of the gate of the transistor 1201 is lowered. On the other hand, the potential VLINE of the signal line 12 is lowered by the transistor 212 as the current source according to a change in a bias state of the transistor 1201. Then, the potential VFD of the FD 105 becomes higher than the value obtained by adding the threshold voltage of the transistor 104 to the potential VLINE. In other words, the transistor 104 is turned ON.

As a result, the potential VLINE of the signal line 12 does not become lower than a value of the FD 105 and the transistor 104 —the threshold voltage between the potential VFD. Further, a difference between the potential of the gate of the transistor 1201 and the potential VLINE of the signal line 12 becomes smaller than the threshold voltage of the transistor 1201. In other words, the transistor 1201 is turned OFF. Since the transistor 1201 is turned OFF, the voltage VOUT of the output node becomes approximately equal to the power source voltage VDD.

In this regard, the source of the transistor 104 and the source of the transistor 1201 are connected to each other, so that a timing when the transistor 1201 shifts from ON to OFF corresponds to a timing when the voltage VFD and the voltage of the reference signal VRAMP are inverted. In other words, the voltage VOUT of the output node is changed from the power source voltage VDD * (R2+R3)/(R1+R2+R3) to the power source voltage VDD before and after the voltage VFD and the voltage of the reference signal VRAMP are inverted. The change in the voltage of the output node is detected, and accordingly the voltage VFD and the reference signal can be compared with each other.

In order to detect the change in the voltage easier, it is desirable that the voltage VOUT of the output node when the transistor 1201 is in the ON state is sufficiently lower than the voltage VOUT of the output node when the transistor 1201 is in the OFF state. In that case, the voltage VLINE of the signal line 12 is also low. However, as described above, the transistor 104 is required to be turned OFF in an initial state. In other words, it is necessary that the voltage VFD is lower than the voltage VLINE of the signal line 12 by an amount equal to or larger than the threshold voltage. In other words, a range in which the voltage VFD can be obtained is narrowed.

If the transistor 104 is in the ON state in the initial state, the voltage VLINE of the signal line 12 is maintained at a value of the voltage VFD —the threshold voltage of the transistor 104. In other words, there is a possibility that a change amount of the voltage VOUT of the output node becomes small, and the inversion of the voltage VFD and the voltage of the reference signal VRAMP cannot be detected.

As described above, according to the comparative example in FIG. 7, the dynamic range of the input node of the transistor 104 in which the transistor 1201 can be operated is narrowed. FIG. 7 illustrates the case in which the PMOS transistor is disposed between the transistor 1201 and the power source voltage VDD, however, the same can be applied to a case of the NMOS transistor.

However, according to the configuration of the present exemplary embodiment illustrated in FIG. 2, a voltage corresponding to the voltage between the gate and the source of the transistor 211 is supplied between the gate and the source of the transistor 215. Thus, a transistor to be a load is not necessary to be disposed between the transistor 211 and the power source voltage VDD. Further, a potential supplied to the drain of the transistor 211 in FIG. 2 becomes higher compared with a potential supplied to the drain of the transistor 1201 in FIG. 7.

Thus, a potential of the source of the transistor 211 can be set higher than the potential of the source of the transistor 1201 in FIG. 7. Further, the potential of the input node of the transistor 104 in FIG. 2 can be set higher compared with the potential of the input node of the transistor 104 in FIG. 7. In other words, an operation voltage range of the transistor 211 can be largely secured with respect to the potential of the input node of the transistor 104. Thus, the dynamic range of the input node of the transistor 104 can be expanded.

According to the present exemplary embodiment, the ratio of the current mirror circuit 223 constituted of the transistors 216 and 217 is 1:2. However, the ratio is not limited to this. Further, the magnitude of the current ILINE generated in the first current source 222 is equivalent to the magnitude of the reference current generated in the second current source 224. However, the magnitudes may be different.

In response to the reverse of the relationship between the potential VFD and the reference signal VRAMP, a current value of each unit can be set in such a manner that the magnitude of the reference current Iref output from the second current source 224 is regarded as a threshold value, and the magnitude of the current I4 output from the current mirror circuit 223 will change across the threshold value.

For example, the mirror ratio of the current mirror circuit 223 may be set to 1:1, and the magnitude of the reference current Iref generated in the second current source may be set to half of the current ILINE generated in the first current source 222. As described above, the current mirror circuit ratio and a constant current value may be set so that the level of the output signal VOUT is changed across a logical determination level (the H level and the L level) of the latch circuit 206 in the latter stage. This configuration can be similarly applied to other exemplary embodiments.

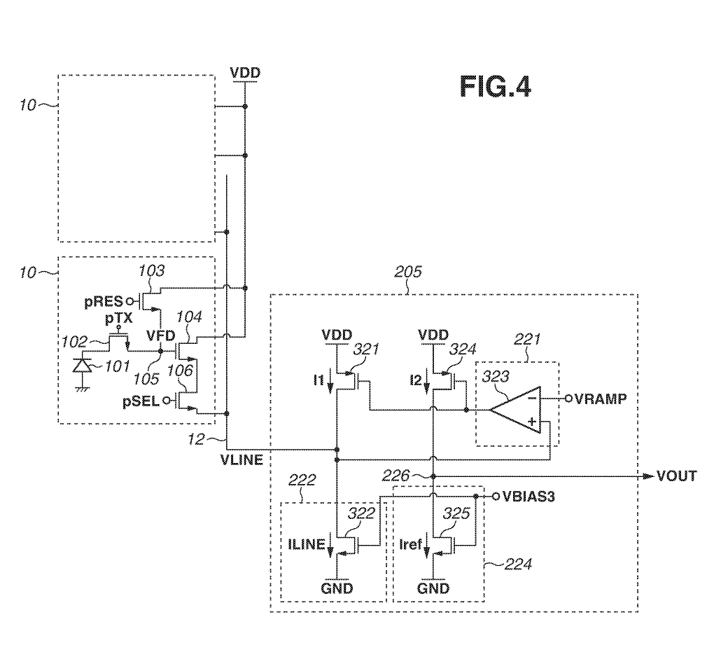

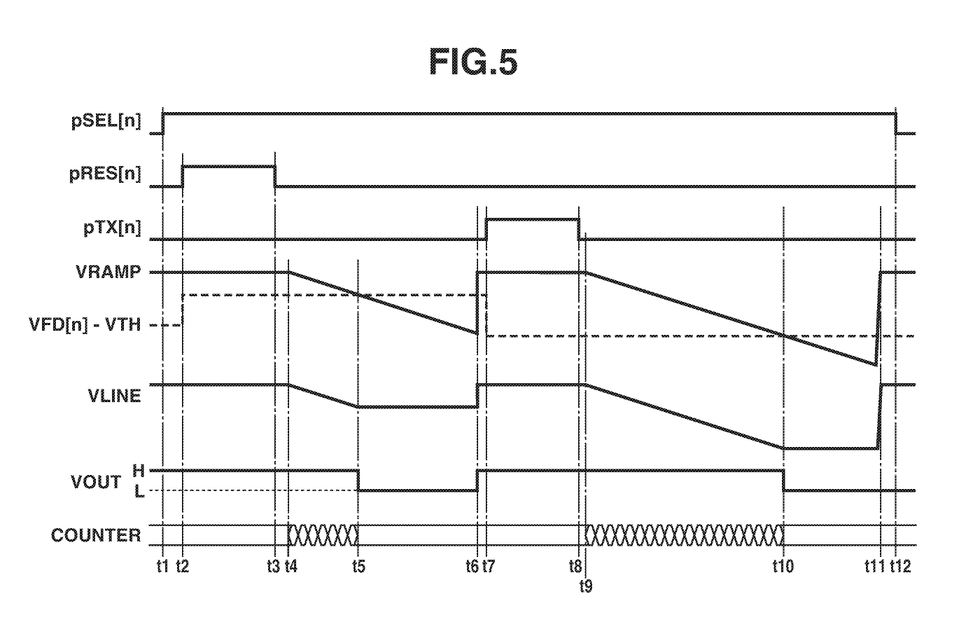

According to a second exemplary embodiment, an entire configuration of the image capturing apparatus 1 is the same as that of the first exemplary embodiment. In other words, FIG. 1 is a block diagram schematically illustrating the entire configuration of the image capturing apparatus 1 according to the present exemplary embodiment. The present exemplary embodiment is described with reference to FIGS. 4 and 5. The present exemplary embodiment is different from the first exemplary embodiment at a configuration of a comparator circuit. Points different from the first exemplary embodiment are mainly described below. Regarding points similar to the first exemplary embodiment, descriptions thereof are omitted.

FIG. 4 is an equivalent circuit diagram illustrating the pixel 10 and the comparator circuit 205 in the image capturing apparatus 1. The configuration of the pixel 10 is similar to that according to the first exemplary embodiment, and thus the descriptions thereof are omitted. A comparator circuit according to the present exemplary embodiment includes a PMOS transistor 321, the first current source 222, the control unit 221, and the second current source 224.

A transistor 322 constitutes the first current source 222. A gate of the transistor 322 is supplied with a bias voltage VBIAS3. A source of the transistor 322 is supplied with the ground potential GND. A drain of the transistor 322 is connected to the signal line 12 and a non-inversion input terminal of a differential amplifier circuit 323. The drain of the transistor 322 is further connected to a drain of the PMOS transistor 321. The bias voltage VBIAS3 controls magnitude of the current ILINE output from the first current source 222.

The control unit 221 includes the differential amplifier circuit 323. The non-inversion input terminal of the differential amplifier circuit 323 is connected to the signal line 12. An inversion input terminal of the differential amplifier circuit 323 is supplied with the reference signal VRAMP output from the reference signal output circuit unit 202. An output terminal of the differential amplifier circuit 323 is connected to a gate of the PMOS transistor 321 and a gate of the PMOS transistor 324.

The gate of the PMOS transistor 321 is connected to the gate of the PMOS transistor 324 and the output terminal of the differential amplifier circuit 323. A source of the PMOS transistor 321 is supplied with the power source voltage VDD without a transistor to be a load. The drain of the PMOS transistor 321 is connected to the signal line 12. The current I1 flows through the PMOS transistor 321. According to the present exemplary embodiment, the source of the transistor 104 and the drain of the PMOS transistor 321 are connected to the drain of the transistor 322 constituting the first current source 222 via the common signal line 12.

A source of the PMOS transistor 324 is supplied with the power source voltage VDD. The gate of the PMOS transistor 324 is connected to the gate of the PMOS transistor 321 and the output terminal of the differential amplifier circuit 323. A drain of the PMOS transistor 324 is connected to a drain of a transistor 325 constituting the second current source 224. The current I2 flows through the PMOS transistor 324.

According to the present exemplary embodiment, a ratio of a channel width of the PMOS transistor 321 to a channel width of the PMOS transistor 324 is 1:2. Thus, the magnitude of the current I2 of the PMOS transistor 324 is about twice as large as the current I1 flowing through the PMOS transistor 321.

The transistor 325 constitutes the second current source 224. A source of the transistor 325 is supplied with the ground potential GND. A gate of the transistor 325 is supplied with the bias voltage VBIAS3. As illustrated in FIG. 4, the gate of the transistor 322 and the gate of the transistor 325 are supplied with the common bias voltage VBIAS3. The reference current Iref flows through the transistor 325. According to the present exemplary embodiment, the magnitude of the current ILINE is approximately equal to the magnitude of the reference current Iref.

A node to which the drain of the transistor 325 and the drain of the PMOS transistor 324 are connected constitutes the output node 226 of the comparator circuit 205. Further, the output signal VOUT output from the output node 226 is input to the latch circuit 206.

Next, a comparison operation of the signal based on the charge generated in the photoelectric conversion unit 101 and the reference signal VRAMP according to the present exemplary embodiment is described. FIG. 5 is a schematic diagram of a timing chart illustrating an example of driving pulses input to pixels in one pixel row for performing the comparison operation.

The driving pulses supplied to the pixels 10 in the N-th row of the pixel rows arranged in the pixel array 100 are described as an example of the driving pulses supplied to the plurality of the pixels 10.

Specifically, the driving pulses pSEL[n], pRES[n], and pTX[n] represent driving pulses input to each transistor in an arbitrary n-th row among driving pulses output from the vertical scanning circuit 201. The potential VFD[n] is a potential of the input node of the transistor 104 of an arbitrary pixel 10 in the n-th row, namely the FD 105. VFD[n]−VTH indicates a potential lowered by a threshold voltage VTH of the transistor 104 from the potential VFD[n] of the FD 105. FIG. 5 illustrates the potential VLINE of the signal line 12, the output signal VOUT of the comparator circuit 205, and the reference signal VRAMP input to the inversion input terminal of the differential amplifier circuit 323.

According to the present exemplary embodiment, the potential VFD of the FD 105 is a gate potential of the transistor 104 of the pixel 10, and the threshold voltage VTH is that of the transistor 104 of the pixel 10. The inequality 1 of the condition that the transistor 104 is turned ON is similar to that of the first exemplary embodiment.

VFD[n]−VLINE>VTH (1)

First, a case when the potential of the reference signal VRAMP is higher than the potential VLINE of the signal line 12 is assumed. An amplification ratio of the differential amplifier circuit 323 is sufficiently high, and thus a potential of the output terminal of the differential amplifier circuit 323 is approximately equal to the ground potential GND.

The source of the PMOS transistor is supplied with the power source voltage VDD, and thus the voltage between the gate and the source of the PMOS transistor 321 is lower than the threshold voltage of the PMOS transistor 321. In other words, the PMOS transistor 321 is turned ON. When the PMOS transistor 321 is turned ON, the current I1 becomes larger, and the potential VLINE of the signal line is raised. Further, when the potential VLINE of the signal line 12 becomes approximately equal to the reference signal VRAMP, the output of the differential amplifier circuit 323 is changed, and the magnitude of the current I1 balances with the magnitude of the current ILINE.

As described above, the potential VLINE is controlled by the differential amplifier circuit 323 to be equal to the potential VRAMP. Thus, the condition that the transistor 104 is turned ON is expressed as an inequality 5 according to the present exemplary embodiment.

VFD[n]−VRAMP>VTH (5)

When the potential VRAMP and the threshold voltage VTH are transposed, an inequality 6 as the condition that the transistor 104 is turned ON is obtained.

VFD[n]−VTH>VRAMP (6)

In other words, when the potential VRAMP of the reference signal is higher than the potential VFD[n] of the FD 105 —the threshold voltage VTH, the transistor 104 is in the OFF state.

Next, a case when the potential of the reference signal VRAMP becomes lower than the potential VFD[n]−the threshold voltage VTH is assumed. At that time, the inequality 6 is satisfied, and the transistor 104 is turned ON.

The transistor 104 operates as the source follower circuit, and the potential VLINE of the signal line 12 is expressed as VLINE=VFD[n]−VTH. In other words, the potential VLINE of the signal line 12 becomes higher than the potential of the reference signal VRAMP. Thus, the potential of the output terminal of the differential amplifier circuit 323 becomes approximately equal to the power source voltage VDD. The voltage between the gate and the source of the PMOS transistor 321 becomes larger than the threshold voltage, and the PMOS transistor 321 is turned OFF.

As described above, VFD[n]−VTH is compared with VRAMP according to the present exemplary embodiment. VFD[n]−VTH1 is an expression in which the threshold value of the transistor 104 is subtracted from the potential input to the gate of the transistor 104. When VFD[n]−VTH1 is large, the transistor 104 is turned ON, and the PMOS transistor 321 is turned OFF. On the other hand, when VRAMP is large, the transistor 104 is turned OFF, and the PMOS transistor 321 is turned ON.

The source of the PMOS transistor 324 is supplied with the power source voltage VDD. The gate of the PMOS transistor 324 is connected to the output terminal of the differential amplifier circuit 323. In other words, the potential supplied to the source and the potential supplied to the gate of the PMOS transistor 324 are respectively approximately equal to the potential supplied to the source and the potential supplied to the gate the PMOS transistor 321.

Thus, when the PMOS transistor 321 is turned ON, the PMOS transistor 324 is also turned ON. Further, when the PMOS transistor 321 is turned OFF, the PMOS transistor 324 is also turned OFF. Therefore, the current I2 of the PMOS transistor 324 is detected, and accordingly a comparison result of VFD[n]−VTH and VRAMP can be obtained.

At the time t1 in FIG. 3, the driving pulse pSEL[n] signal becomes the H level, and the selection transistor 106 enters the ON state. The pixel in the n-th row is electrically connected to the signal line 12. The start voltage of the reference signal VRAMP is set to a potential higher than VFD[n]−VTH. At that time, the PMOS transistor 321 and the PMOS transistor 324 are turned ON.

In the period t2-t6, the AD conversion is performed on the reset potential which is the potential of the FD 105 when the pixel 10 is reset.

Next, at the time t2, the driving pulse pRES[n] becomes the H level, and the reset transistor 103 enters the ON state. Accordingly, the potential VFD of the FD 105 of the pixel in the n-th row becomes the reset potential. The start voltage of the reference signal VRAMP is at the higher potential than VFD[n]−VTH (a reset level). At that time, the potential VFD and the reference signal VRAMP do not satisfy a relationship of the inequality 6, and the transistor 104 enters the OFF state.

Next, at the time t3, the driving pulse pRES[n] becomes the L level, and the reset transistor 103 enters the OFF state.

At the time t4, the potential of the reference signal VRAMP starts to change and is gradually lowered. Further, the counter circuit 203 starts counting at the same time with the start of the change in the reference signal VRAMP. In other words, the count value output from the counter circuit 203 and input to the latch circuit 206 starts to change.

In the period t2-t4, the reference signal VRAMP is in the higher potential than the potential VFD[n] of the signal line 12 —VTH1 and constant. The differential amplifier circuit 323 controls the voltage of the gate of the PMOS transistor 321 so that the inversion input terminal and the non-inversion input terminal thereof are in the virtual short. Specifically, the gate voltage and the drain voltage of the PMOS transistor 321 are controlled so that a current comparable to the current ILINE flows through the PMOS transistor 321.

Since the above-described inequality 6 is not satisfied, the transistor 104 is in the OFF state, and a current 10 flowing through the transistor 104 is very small or zero. Thus, the magnitude of the current I1 of the PMOS transistor 321 converges so as to be the same degree as the magnitude of the current ILINE.

The voltage between the gate and the source of the PMOS transistor 324 becomes approximately the same as the voltage between the gate and the source of the PMOS transistor 321. Due to a difference of a channel width, the magnitude of the current I2 of the PMOS transistor 324 is approximately twice as large as the magnitude of the current I1 of the PMOS transistor 321. On the other hand, the current Iref approximately the same magnitude as the current ILINE flows through the second current source 224. In other words, a current value of the current I2 is larger than a current value of the current Iref.

Thus, the potential of the output node 226 connected to the PMOS transistor 324 is raised, and the potential of the output node 226 becomes stable at a potential at which the current value of the current I2 of the PMOS transistor 324 converges on the current value of the reference current Iref.

In more detail, a difference between the potential output from the differential amplifier circuit 323 and the power source voltage VDD is applied as the bias voltage between the gate and the source of the PMOS transistor 324. In the bias state, a voltage of the drain of the PMOS transistor 324 is controlled so that a voltage at which the magnitude of the current I2 becomes the same degree as the magnitude of the reference current Iref is generated between the drain and the source of the PMOS transistor 324.

The latch circuit 206 in the latter stage receives the potential of the output signal VOUT at that time as the high potential (the potential at the H level). In other words, the potential of the output signal VOUT of the comparator circuit 205 at that time is a potential higher than a logical threshold of the latch circuit 206 in the latter stage.

In the period t4-t5, the reference signal VRAMP supplied to the non-inversion input terminal of the differential amplifier circuit 323 is lowered, and the potential VLINE of the signal line 12 connected to an inversion input terminal is also lowered by the virtual short of the differential amplifier circuit 323.

At the time t5, a magnitude relationship between the reference signal VRAMP and the potential VFD[n]−VTH is inverted. When the reference signal VRAMP becomes smaller than the potential VFD−VTH, the inequality 6 is satisfied, and the transistor 104 is turned ON. Thus, the potential VLINE of the signal line 12 is maintained at the potential VFD[n]−VTH. Further, the potential supplied to the gate of the PMOS transistor 321 and the gate of the PMOS transistor 324 via the differential amplifier circuit 323 becomes approximately equal to the power source voltage VDD. Thus, the PMOS transistor 321 and the PMOS transistor 324 are turned OFF.

The current I2 of the PMOS transistor 324 becomes almost zero, and the potential of the output node 226 is lowered. In other words, the output signal VOUT of the comparator circuit 205 input to the latch circuit 206 becomes a low potential. According to the change in the output signal VOUT, the latch circuit 206 holds the count value output from the counter circuit 203.

At the time t6, the reference signal VRAMP is reset to a potential the same as that at the time t1. By the operations so far, the AD conversion when the output signal of the pixel 10 is the reset signal is completed.

Further, the latch circuit 206 outputs the held digital signal to the signal line 13 at a timing when being controlled by the driving pulse output from the horizontal scanning circuit 207.

In the period t5-t6, if the reference signal VRAMP is lowered to be smaller than the potential VFD−VTH, the transistor 104 is in the ON state, so that the potential VLINE is not lowered than the potential at the time t5. Thus, the potential VLINE is not lowered than the potential level of VFD[n]−VTH.

In the period t7-t11, the AD conversion is performed on an optical signal of the pixel 10. At the time t7, the driving pulse pTX[n] becomes the H level, and the transfer transistor 102 enters the ON state. At the time t8, the driving pulse pTX[n] becomes the L level, and the transfer transistor 102 enters the OFF state.

Accordingly, the charge generated in the photoelectric conversion unit 101 in the period t3-t8 is transferred to the FD 105, and the potential of the gate of the transistor 104 is changed.

Driving in the period t9-t11 is similar to that in the period t4-t6, and thus the description thereof is omitted. At the time t12, the driving pulse pSEL becomes the L level, and the selection transistor 106 enters the OFF state.

When the present exemplary embodiment is applied, a dynamic range of a voltage signal can be handled and expanded as with the first exemplary embodiment. Expansion of the dynamic range leads expansion of a range of an optical signal can be handled and accuracy improvement of an output signal.

According to the present exemplary embodiment, it is described that the ratio of the channel width of the PMOS transistor 321 to the channel width of the PMOS transistor 324 is 1:2. However, the ration is not limited to this. For example, a size ratio of the PMOS transistor 321 to the PMOS transistor 324 may be set to 1:1, and the magnitude of the reference current Iref flowing through the second current source 224 may be half of the current ILINE. As described above, the current mirror circuit ratio and a constant current value may be set so that the level of the output signal VOUT is changed across a logical determination level (the H level and the L level) of the latch circuit 206 in the latter stage.

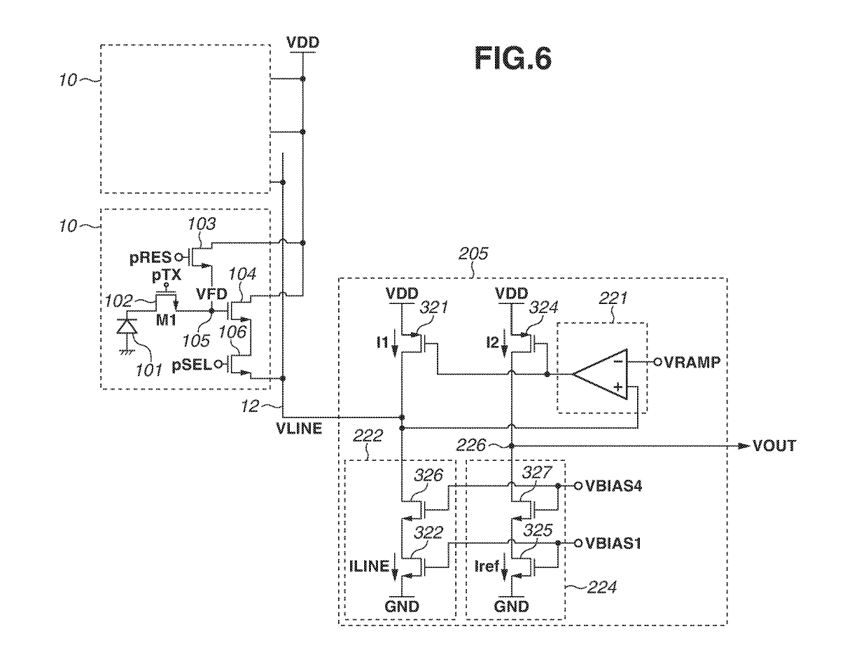

FIG. 6 is an equivalent circuit diagram according to a third exemplary embodiment. FIG. 6 illustrates a configuration in which the first current source and the second current source are modified in the equivalent circuit diagram in FIG. 4. Descriptions of components having the similar functions are omitted.

In the equivalent circuit diagram according to the present exemplary embodiment, the first current source and the second current source may be a cascode circuit configuration. Specifically, the first current source is constituted of a transistor 326 and the transistor 322, and the second current source is constituted of a transistor 327 and the transistor 325.

According to the above-described configuration, current fluctuation in the current ILINE due to potential fluctuation in the signal line 12 can be suppressed in the first current source 222. The current fluctuation in the current ILINE due to potential fluctuation in the output node 226 can be suppressed in the second current source 224. Thus, the AD conversion can be accurately performed.

The configuration of the present exemplary embodiment can be applied to all of the exemplary embodiments.

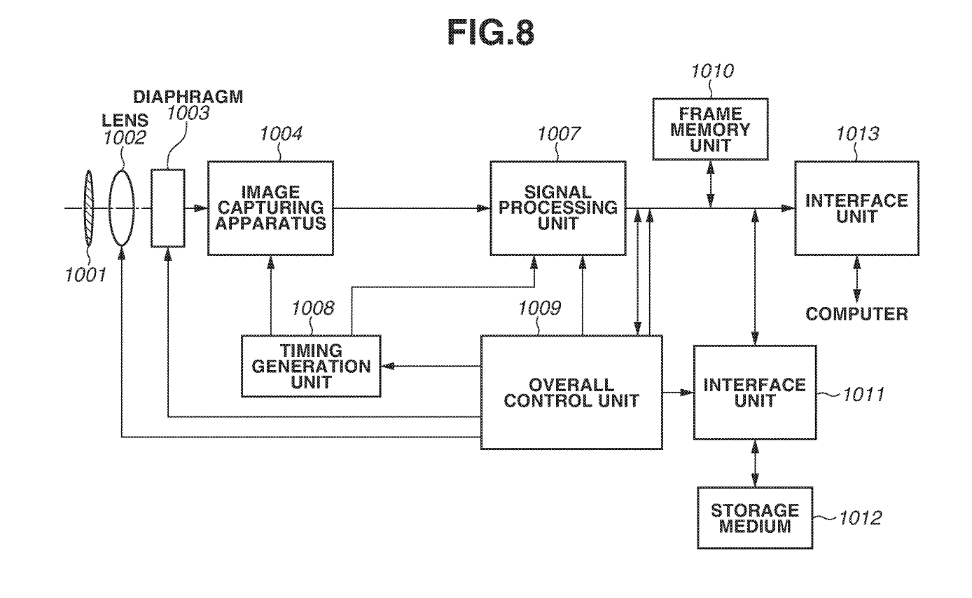

A fourth exemplary embodiment of an image capturing system is described. The image capturing system may include a digital still camera, a digital camcorder, a camera head, a copying machine, a facsimile, a mobile phone, an on-vehicle camera, an observation satellite, and the like. FIG. 8 is a block diagram illustrating a digital still camera as an example of the image capturing system.

In FIG. 8, the digital still camera includes a barrier 1001 for protecting a lens, a lens 1002 for forming an optical image of an object on the image capturing apparatus 1004, and a diaphragm 1003 for changing a light amount passing through the lens 1002. The image capturing apparatus 1004 is the one described in each of the above exemplary embodiments and converts the optical image formed by the lens 1002 into image data. It is assumed that an AD conversion unit is formed on a semiconductor substrate in the image capturing apparatus 1004.

A signal processing unit 1007 performs various correction on captured image data output from the image capturing apparatus 1004 and compresses the data. In FIG. 8, a timing generation unit 1008 outputs various timing signals to the image capturing apparatus 1004 and the signal processing unit 1007, and an overall control unit 1009 entirely controls the digital still camera.

A frame memory unit 1010 temporarily stores the image data. An interface unit 1011 records and reads the captured image data to and from a storage medium. A storage medium 1012 is a detachable storage medium, such as a semiconductor memory for recording and reading the captured image data. An interface unit 1013 communicates with an external computer and the like. The timing signal may be input from the outside of the image capturing system, and the image capturing system may include at least the image capturing apparatus 1004 and the signal processing unit 1007 for processing an image capturing signal output from the image capturing apparatus 1004.

According to the present exemplary embodiment, the configuration is described in which the image capturing apparatus 1004 and the AD conversion unit are provided on different semiconductor substrates. However, the image capturing apparatus 1004 and the AD conversion unit may be formed on the same single semiconductor substrate. Further, the image capturing apparatus 1004 and the signal processing unit 1007 may be formed on the same single semiconductor substrate.

Further, each pixel 10 may be configured to include a first photoelectric conversion unit 101A and a second photoelectric conversion unit 101B which are similar to the photoelectric conversion unit 101 shown in FIG. 2. The signal processing unit 1007 may be configured to process a signal based on a charge generated in the first photoelectric conversion unit 101A and a signal based on a charge generated in the second photoelectric conversion unit 101B and obtain distance information from the image capturing apparatus 1004 to an object.

According to the exemplary embodiment of the image capturing system, the image capturing apparatus either of the first exemplary embodiment and the second exemplary embodiment is used as the image capturing apparatus 1004. According to the above-described configuration, an image of which a dynamic range is expanded can be obtained.

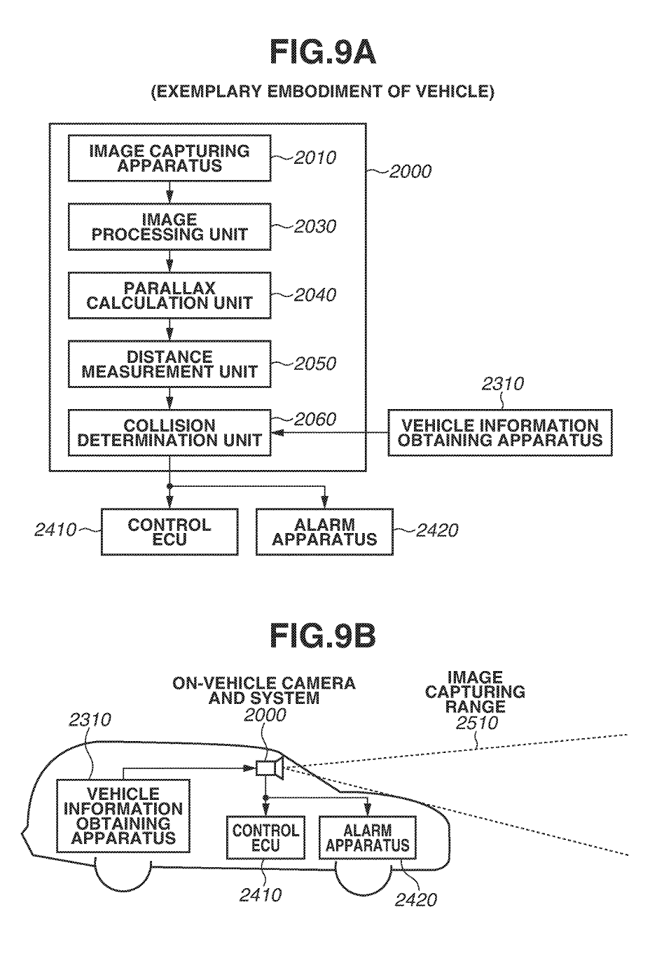

FIGS. 9A and 9B illustrate examples of the image capturing system regarding an on-vehicle camera according to a fifth exemplary embodiment. An image capturing system 2000 includes an image capturing apparatus 2010 according to the above-described exemplary embodiments. The image capturing system 2000 includes an image processing unit 2030 for performing image processing on a plurality of image data pieces obtained by the image capturing apparatus 2010 and a parallax calculation unit 2040 for calculating a parallax (a phase difference in a parallax image) from the plurality of image data pieces obtained by the image capturing system 2000.

The image capturing system 2000 further includes a distance measurement unit 2050 for calculating a distance to an object based on the calculated parallax and a collision determination unit 2060 for determining whether there is a possibility of collision based on the calculated distance.

The parallax calculation unit 2040 and the distance measurement unit 2050 are examples of a distance information obtaining unit for obtaining distance information to an object. In other words, the distance information is information regarding a parallax, a defocus amount, the distance to the object, and the like. The collision determination unit 2060 may determine the possibility of collision using any of the distance information pieces.

The distance information obtaining unit may be realized by exclusively designed hardware or a software module. Further, the distance information obtaining unit may be realized by a field programmable gate array (FPGA), an application specific integrated circuit (ASIC), and the like. Furthermore, the distance information obtaining unit may be realized by combinations of these components

The image capturing system 2000 is connected to a vehicle information obtaining apparatus 2310 and can obtain vehicle information pieces, such as a vehicle speed, a yaw rate, and a steering angle. Further, the image capturing system 2000 is connected to an engine control unit (ECU) 2410 which is a control apparatus outputting a control signal for generating a braking force to the vehicle based on a determination result of the collision determination unit 2060.

Furthermore, the image capturing system 2000 is connected to an alarm apparatus 2420 for raising an alarm to a driver based on the determination result of the collision determination unit 2060. For example, when the possibility of collision is high as the determination result of the collision determination unit 2060, the control ECU 2410 performs vehicle control to avoid collision or reduce a damage by applying the brake, releasing the accelerator, suppressing an engine output, and the like. The alarm apparatus 2420 warns a user by sounding the alarm, displaying alarm information on a screen of a car navigation system and the like, applying vibration on a seat belt and a steering, and the like.

According to the present exemplary embodiment, the image capturing system 2000 captures an image around, for example, ahead or behind of the vehicle. FIG. 9B illustrates the image capturing system when capturing an image in front of the vehicle. The example in which the control is performed so as not to collide with another vehicle is described above, however, the present exemplary embodiment can be applied to control of automatic driving for following another vehicle and control of automatic driving not for deviating from a lane. Further, the image capturing system can be applied to not only a vehicle such as an automobile but also a mobile body (moving apparatus) such as a ship, an aircraft, and an industrial robot. In addition, the image capturing system can be widely applied to devices using object recognition such as Intelligent Transport Systems (ITS) without limiting to a mobile body.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2016-150329, filed Jul. 29, 2016, which is hereby incorporated by reference herein in its entirety.

What is claimed is:

1. An image capturing apparatus comprising:
a plurality of pixels including a photoelectric conversion unit and a first transistor having a gate to which a signal based on a charge generated in the photoelectric conversion unit is input;
a signal line connected to the plurality of pixels;
a second transistor including a source electrically connected to the first transistor via the signal line and including a gate supplied with a signal corresponding to a reference signal of which a potential changes at a predetermined gradient with time;
a first current source configured to supply a source current to the first transistor and the second transistor;
a control unit configured to control a voltage between a gate and a source of a third transistor to be a voltage corresponding to a voltage between the gate and the source of the second transistor; and
a comparator circuit configured to compare a first current flowing through the third transistor with a reference current.

2. The image capturing apparatus according to claim 1,
wherein the second transistor and the third transistor have same conductivity type as that of the first transistor, and
wherein a drain of the second transistor and a drain of the third transistor are connected to a power source voltage without a transistor, and a source of the second transistor is connected to the signal line.

3. The image capturing apparatus according to claim 2, wherein a gate of the second transistor and a gate of the third transistor are supplied with the common reference signal.

4. The image capturing apparatus according to claim 2,
wherein the control unit comprises:
a fourth transistor having a reverse conductivity type to that of the first transistor; and
a differential amplifier circuit in which a non-inversion input terminal is connected to the signal line, an inversion input terminal is connected to a source of the fourth transistor, and an output terminal is connected to a gate of the fourth transistor, and
wherein a source of the third transistor is connected to the source of the fourth transistor and the inversion input terminal.

5. The image capturing apparatus according to claim 4, further comprising:
a current mirror circuit configured to receive the first current,
wherein a drain of the fourth transistor is connected to an input node of the current mirror circuit, and
wherein the fourth transistor switches electrical connection and disconnection between the third transistor and the current mirror circuit.

6. The image capturing apparatus according to claim 5, further comprising:
a second current source configured to be connected to an output node of the comparator circuit and supply the reference current to the output node,
wherein an output node of the current mirror circuit is connected to the output node of the comparator circuit and the second current source.

7. The image capturing apparatus according to claim 6, wherein a potential of the output node is higher in a case that the reference current is larger with respect to the first current via the current mirror circuit than in a case that the reference current is smaller.

8. The image capturing apparatus according to claim 6, wherein a transistor constituting the first current source and a transistor constituting the second current source have a cascode type circuit configuration.

9. The image capturing apparatus according to claim 6,
wherein the current mirror circuit comprises:
a fifth transistor and a sixth transistor having same conductivity type as that of the first transistor,
wherein a source of the fifth transistor and a source of the sixth transistor are grounded, and a gate of the fifth transistor is connected to a drain of the fifth transistor and a gate of the sixth transistor,
wherein the drain of the fifth transistor constituting the input node of the current mirror circuit is connected to the gate of the fifth transistor and the drain of the fourth transistor, and
wherein a drain of the sixth transistor constituting the output node of the current mirror circuit is connected to the output node and the second current source.

10. The image capturing apparatus according to claim 1,
wherein the second transistor and the third transistor have a reverse conductivity type to that of the first transistor; and
wherein the source of the second transistor and the source of the third transistor are connected to a power source voltage without a transistor, and a drain of the second transistor is connected to the signal line.

11. The image capturing apparatus according to claim 10, wherein the control unit comprises
a differential amplifier circuit in which an inversion input terminal is supplied with the reference signal, a non-inversion input terminal is connected to the signal line, and an output terminal is connected to a gate of the second transistor and a gate of the third transistor.

12. The image capturing apparatus according to claim 10, further comprising:
a second current source configured to be connected to an output node of the comparator circuit and supply the reference current to the output node,
wherein a drain of the third transistor is connected to the output node of the comparator circuit and the second current source.

13. The image capturing apparatus according to claim 12, wherein a potential of the output node is higher in a case that the reference current is larger with respect to the first current than in a case that the reference current is smaller with respect to the first current.

14. The image capturing apparatus according to claim 12, wherein a transistor constituting the first current source and a transistor constituting the second current source have a cascode type circuit configuration.

15. An image capturing system comprising:
an image capturing apparatus according to claim 1; and
a processing apparatus configured to process a signal output from the image capturing apparatus to obtain an image signal.

16. A movable body comprising:
an image capturing apparatus according to claim 1;
a processing apparatus configured to perform processing on a signal output from the image capturing apparatus; and
a movable body controller configured to control the mobile body based on a result of the processing.
